(19) United States
(12) Patent Application Publication
(10) Pub. No.: US 2013/0157407 A1
(43) Pub. Date: Jun. 20, 2013

(54) APPARATUS FOR INLINE PROCESSING OF Cu(In,Ga)(Se,S)2 EMPLOYING A CHALCOGEN SOLUTION COATING MECHANISM

(71) Applicant: Weí Liu, Sunnyvale, CA (US)

(72) Inventor: Weí Liu, Sunnyvale, CA (US)

(73) Assignee: Intermolecular, Inc., San Jose, CA (US)

(21) Appl. No.: 13/330,903

(22) Filed: Dec. 20, 2011

(51) Int. Cl. H01L 31/0272; B05D 1/36; C23C 14/34

(52) U.S. Cl. 438/95; 204/192.15; 257/E31.008

(57) ABSTRACT

Apparatus and method for the formation of copper indium gallium diselenide (CIGS) photovoltaic devices are disclosed. In one aspect, an inline production apparatus and method is described comprising sputter deposition and solution based selenization, followed by thermal annealing. Copper, indium and gallium are sputter deposited on one or more substrates in a sputter chamber. The substrates are then coated with a solution comprising a source of selenium in a selenium coating chamber. After coating with the selenium based solution, the substrates are heated in an annealing chamber to form a CIGS layer on the substrate. Substrates are conveyed though each of the chambers in a continuous manner, which provides for low-cost, fast throughput, inline production of CIGS photovoltaic devices.

### TECHNICAL FIELD

The present disclosure relates generally to the field of photovoltaic devices and processing, and more particularly to apparatus and methods for inline processing of copper indium gallium diselenide (CIGS) photovoltaic devices.

### BACKGROUND

Solar cells are photovoltaic (PV) devices that convert light into electrical energy. Photovoltaic devices have been developed as clean, renewable energy sources to meet growing energy demand. Photovoltaic devices are being developed for a wide number of commercial markets including residential rooftops, commercial rooftops, utility-scale PV projects, building integrated PV (BIPV), building applied PV (BAPV) applications and the like. Widespread adoption of PV technology has not yet arrived, due in part to the high cost per watt for PV devices, particularly when compared to traditional electrical utility costs.

Currently, crystalline silicon based solar cells or photovoltaic devices (single crystal, multicyrstalline and polycrystalline) are the dominant technologies in the market. Crystalline silicon (cSi) solar cells must use a thick substrate (>100 um) of silicon to absorb the sunlight since it has an indirect band gap, which also leads to a low absorption coefficient for crystalline silicon. The use of a thick substrate also means that the crystalline silicon solar cells must use high quality material to provide long carrier lifetimes to allow the carriers to diffuse to the contacts. Therefore, crystalline silicon solar cell technologies lead to increased costs.

Thin film photovoltaic (TFPV) devices have received increased interest as a replacement to crystalline silicon based PV devices. A variety of TFPV devices have been developed, such as TFPV devices based on amorphous silicon (a-Si), copper indium gallium diselenide (CIGS), and cadmium telluride (CdTe). Among these thin film technologies, some have gained commercial success and achieved lower cost per watt than conventional Si-based PV devices. For example, CdTe based thin film PV devices have demonstrated lower costs than Si based PV devices in recent years. CIGS based PV devices have garnered particular interest due to high demonstrated efficiencies when compared to the other TFPV materials.

Currently, CIGS layers used in PV devices are typically formed using vacuum based deposition processes where individual metal sources of copper, indium, gallium and selenium are evaporated towards a substrate in a vacuum chamber. Such vacuum based evaporation deposition processes are expensive, require high capital costs, and precise processing. Material utilization is poor, which further adds to the high manufacturing costs.

Co-evaporation of selenium onto a high temperature substrate in a high temperature environment causes many issues (such as Se corrosion, Se flux control) and is one of the largest challenges and bottlenecks in production of CIGS. Evaporation processes typically have a low material utilization rate and a limited material deposition rate, thus resulting in high raw material cost and low throughput. Process stability is another significant challenge for CIGS manufacturing using co-evaporation based techniques. Achieving uniform film deposition across a large-area substrate is another significant challenge with currently known methods.

Another known selenization technique is carried out in a selenization furnace using a source of selenium such as H₂Se. H₂Se poses a significant safety risk and thus dilute H₂Se is typically used as the reactant. This increases the reaction time, which can be on the order of hours. Such furnaces are typically operated in batch mode, which significantly limits throughput. Moreover, many furnaces are needed to achieve desirable production volume, thus increasing capital and operating costs.

The manufacture of TFPV devices entails the integration and sequencing of many unit processing steps. As an example, TFPV manufacturing typically includes a series of processing steps such as cleaning, surface preparation, deposition, patterning, etching, thermal annealing, and other related unit processing steps. The precise sequencing and integration of the unit processing steps enables the formation of functional devices meeting desired performance metrics such as efficiency, power production, and reliability.

Thus, further developments are needed, particularly apparatus and methods that lower the cost of manufacturing CIGS based PV devices and address some of the limitations of the current manufacturing techniques.

### SUMMARY

Apparatus and method for the formation of copper indium gallium diselenide (CIGS) photovoltaic devices are disclosed. In one aspect, an in-line production apparatus and method is described comprising sputter deposition and solution based selenization, followed by thermal annealing. Copper, indium and gallium are sputter deposited on one or more substrates in a sputter chamber. The substrates are then coated with a solution comprising a source of selenium in a selenium coating chamber. After coating with the selenium based solution, the substrates are heated in an annealing chamber to form a CIGS layer on the substrate. Substrates are conveyed though each of the chambers in a continuous manner, which provides for low-cost, fast throughput, inline production of CIGS photovoltaic devices.

In some embodiments, an apparatus for production of copper indium gallium diselenide (CIGS) layer on a substrate is provided, comprising at least one first chamber having one or more of copper, cu-gallium or indium targets and configured to sputter copper, gallium or indium metals onto one or more substrates, second chamber configured to coat the one or more substrates with a solution comprising a source of selenium; a third chamber configured to heat the one or more substrates to form a CIGS layer; and an in-line system supporting the one or more substrates and configured to convey the one or more substrates sequentially through each of the first, second and third chambers.

In some embodiments, an apparatus for production of copper indium gallium diselenide (CIGS) layers on a substrate is disclosed, comprising at least one sputter chamber having one or more of copper (Cu), indium (In) gallium (Ga) (the sputter target being a binary copper-gallium target, or their alloy targets and configured to sputter copper, indium and gallium metals onto one or more substrates; a selenium coating chamber configured to coat the one or more substrates with a solution comprising a source of selenium; an annealing chamber configured to heat the one or more substrates to form a CIGS layer; and a conveyor system supporting the one or more substrates and configured to move the one or more substrates through each of the sputter, coating and annealing chamber.

In some embodiments, a method for the formation of copper indium gallium diselenide (CIGS) layers on a substrate is provided, comprising: sputter depositing copper, indium and gallium metal onto one or more substrates; coating the one or more substrates with a solution comprising a source of selenium; and heating the coated substrate to form the CGIS layer, wherein the one or more substrates are conveyed though each of the sputter depositing, coating and heating steps in a continuous manner.

In some embodiments, the selenium solution is coated on the substrate by any one of more of the following techniques: dip coating, slit casting, gap coating, spray coating and the like. In some embodiments the selenium solution is coated on the substrate by ink-jet coating techniques. In some embodiments, the selenium solution comprises a source of selenium dissolved in a solvent.

In some embodiments the Se layer is formed having a desired thickness. The thickness of the Se layer may be varied in the coating chamber by adjusting any one or more of: thickness of the solution, concentration of Se in the solution, viscosity of the solution, or speed of coating the solution on the substrate.

### BRIEF DESCRIPTION OF THE DRAWINGS

The techniques of the present invention can readily be understood by considering the following detailed description in conjunction with the accompanying drawings, in which:

FIG. 1 is a schematic diagram showing an inline apparatus or system according to some embodiments of the present disclosure;

FIG. 2A-2C are schematic diagrams showing an inline sputter chamber, coating chamber and annealing chamber, respectively according to some embodiments of the present invention; and

FIG. 3 is flowchart illustrating methods of the present disclosure according to some embodiments.

### DETAILED DESCRIPTION

A detailed description of one or more embodiments is provided below along with accompanying figures. The detailed description is provided in connection with such embodiments, but is not limited to any particular example. Numerous specific details are set forth in the following description in order to provide a thorough understanding and are not intended to limit the scope of the invention in any way. These details are provided for the purpose of example and the described techniques may be practiced according to the claims without some or all of these specific details.

As used herein, the term “CIGS” is understood to represent the entire range of related alloys denoted by Cu_{z}In₍₁₋ₓ₎GaₓS_{(2+w)(1-y)}Se_{(2+w)y}, where 0.5≦z≦1.5, 0≦x≦1, 0≦y≦1, −0.2≦w≦0.5 Any of these materials may be further doped with a suitable dopant.

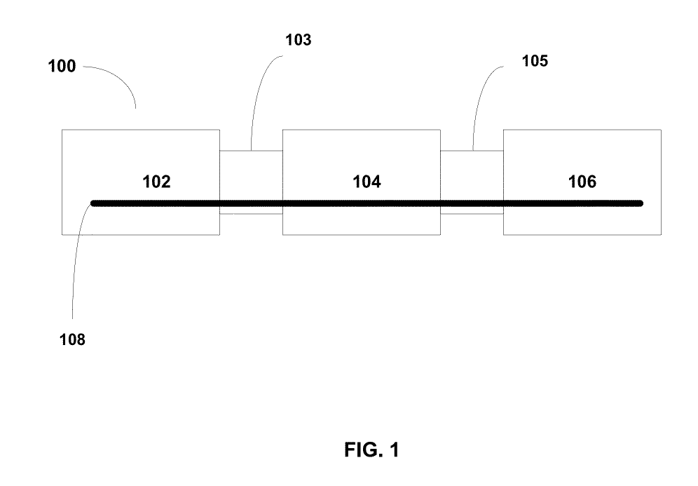

FIG. 1 shows a simplified inline apparatus 100 configured to form copper indium gallium diselenide (CIGS) layers on a substrate. In general, the inline apparatus 100 includes at least one vacuum or sputter deposition chamber 102 coupled via loadlock 103 to at least one coating chamber 104. The coating chamber 104 is coupled to at least one annealing chamber 106 optionally via loadlock 105. If coating chamber 104 and annealing chamber 106 are operated at the same pressure, the loadlock 105 is not needed. A conveyor system 108 moves one or more substrates (not shown) through each of the sputter 102, coating 104 and annealing 106 chambers in a continuous manner.

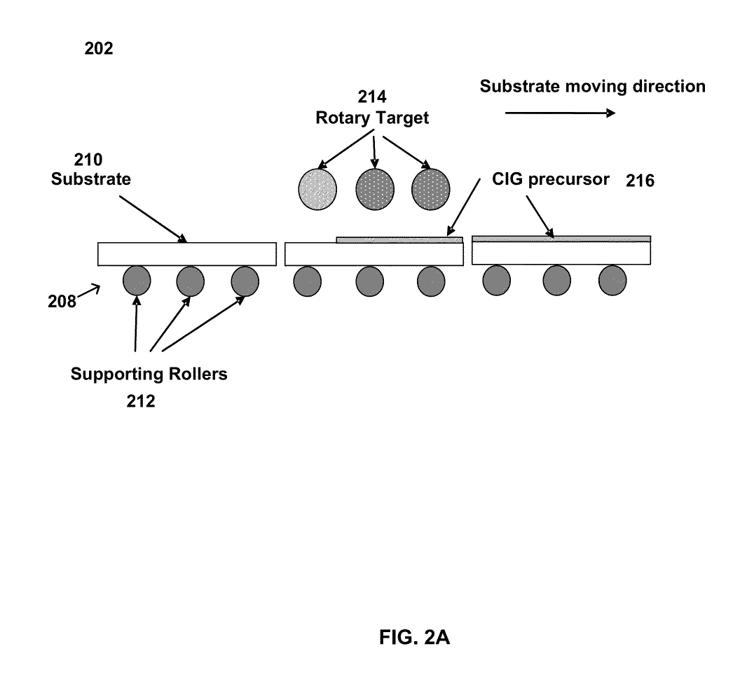

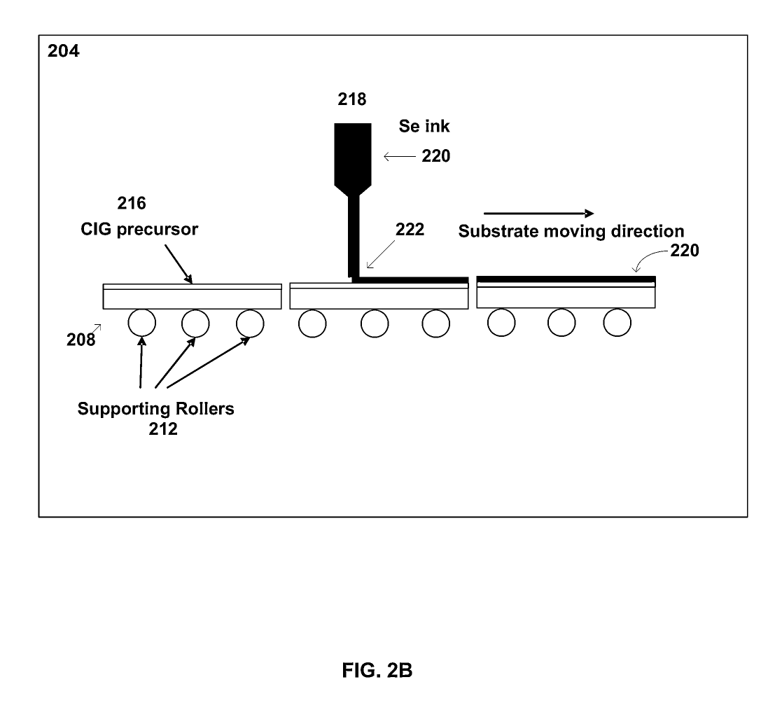

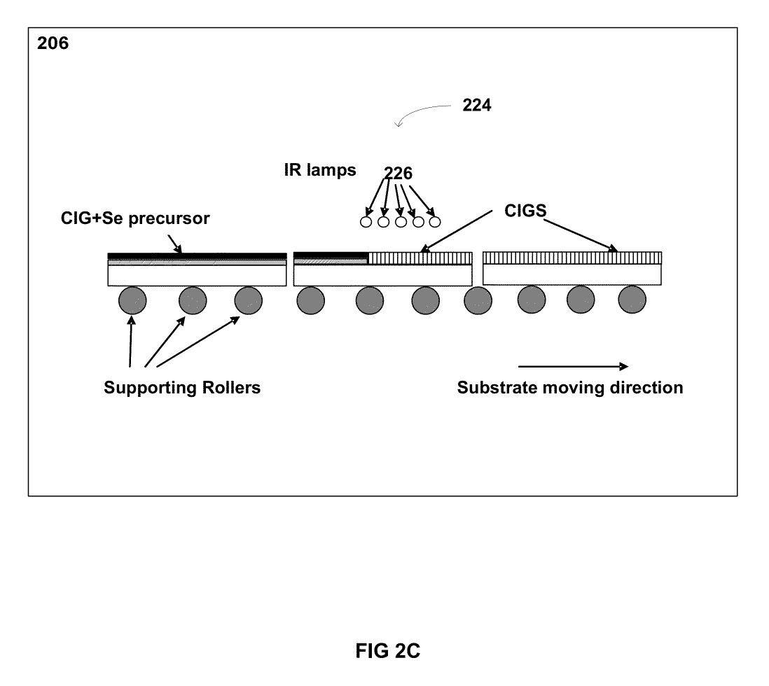

Referring to FIGS. 2A-2C, some exemplary embodiments of the chambers are shown in more detail. While specific configurations are described herein, it will be appreciated that other configurations are possible within the spirit of the teaching and that the invention is not limited to the specific embodiments described and illustrated in the figures.

In some embodiments, sputter chamber 202 includes a conveyor 208 configured to support one or more substrate 210 and to convey the substrates 210 through the chamber 202. The conveyor 208 may be any suitable design and in some embodiments is comprised of a plurality of support rollers 212. In some embodiments, the conveyor 208 may be a continuous belt, rollers, parallel chains, “walking beam”, strings, and the like.

The substrates 210 may be any suitable photovoltaic substrate. In some embodiments, suitable substrates comprise glass, coated glass, float glass, low-iron glass, borosilicate glass, specialty glass for high temperature processing, stainless steel, carbon steel, aluminum, copper, titanium, molybdenum, polyimide, plastics, cladded metal foils, flexible substrates with glass-like coatings such as SiO₂ (optionally Na doped), TiO₂(optionally Na doped), and the like. In FIGS. 2A-2C the substrates 210 are comprised of a plurality of discrete pieces, however the substrate can also be a continuous substrate such as a continuous metal foil, or a continuous sheet of polyimide, and the like. In the embodiment where a continuous substrate is processed, the conveyor 208 is configured to support roll-to-roll processing.

The sputter chamber 202 includes one or more of copper, gallium and indium or their alloy targets 214 configured to sputter copper, gallium and indium metals onto one or more substrates 210. In some embodiments, the targets are comprised of a copper sputter target, a binary copper-gallium sputter target, and an indium sputter target. As the substrates are conveyed under the sputter targets 214, a precursor layer 216 of copper, indium and gallium is sputtered onto the surface of the substrate 214.

Any suitable type of sputter target 214 may be used. In some embodiments, the sputter targets 214 are comprised of rotary targets. In some embodiments, the sputter targets 214 are comprised of planar targets. The sputter targets 214 may be moveable or tilted as desired to achieve good deposition uniformity of the CIG precursor film across the substrate. As shown in FIG. 2A, the sputter chamber 202 includes three sputter targets 214, however any suitable number may be used.

After the CIG precursor layer 216 is formed on the substrate 210, the substrate is conveyed to coating chamber 204. Typically, the sputter chamber is operated under vacuum and thus a loadlock chamber may be coupled between the sputter 202 and coating 204 chambers in order to move substrates between the chambers while maintaining the vacuum environment in the sputter chamber 202. Specifically, for a continuous substrate setup, one stage or more than one stage buffer chambers may be used to transit the pressure from mTorr range to Torr range or even higher.

Referring to FIG. 2B, the selenium coating chamber 204 is configured to coat the one or more substrates 210 with a solution comprising a source of selenium. The selenium coating chamber 204 includes a selenium coater 218. In some embodiments the selenium coater 218 is configured to provide a liquid solution of selenium that is coated over the substrate 210 as the substrate is conveyed underneath the coater 218. In some embodiments the selenium coater 218 is comprised of a slit-casting or ink-jet type coater having a reservoir 220 and an outlet 222. In some embodiments, the outlet 222 is elongated and substantially coextensive with the width or diameter of the substrate such that the entire surface of the substrate is coated with the selenium solution as the substrates moves under the coater 218. A solution comprising a source of selenium and a solvent is supplied to the reservoir 220. In some embodiments a chalcogen such as Se and/or S dissolved in a solution is used as the source of selenium/sulfur. Examples of suitable solvents include without limitation: hydrazine, hydrous hydrazine, and/or a hydrazine-like solvent, such as ethanolamine, ethylene diamine (EDA), propylene diamine (PDA), dimethyl sulfoxide (DMSO, and mixtures thereof.

A desired amount of the selenium solution is delivered via the outlet 222 to the substrate. Typically, the outlet 222 includes one or more sensors (not shown) configured to determine when a discrete substrate starts to pass under the outlet 222 and when the end of the substrate has been reached. The sensor(s) are coupled to a control system (not shown) which triggers start and stop flow of the solution from the outlet 222 in order to control the flow of solution only when a substrate is present.

Of particular advantage, the inline apparatus of the present disclosure enables control of the selenium amount applied to the substrate. In some embodiments, selenium amount is varied by adjusting the concentration of selenium in the solution. In some embodiments, selenium amount is varied by adjusting the supply rate of the solution from outlet 222 as the substrate is coated. For example, when using the ink-jet type coater, the solution thickness can be tuned by adjusting the flow rate of the solution that is applied to the substrate from the outlet 222.

The selenium coater 218 may be comprised of other suitable solution based coaters, such as for example: a slit casting coater, gap coater, spray coater, spin-on coater, roll coater, blade coater, curtain coater and the like.

Referring to FIG. 2C, once the selenium solution is coated atop the CIG precursor layer, the substrates are conveyed to an annealing chamber 206. The annealing chamber includes a heat source 224 and is configured to heat the one or more substrates to form the CIGS layer. In some embodiments, the heat source is comprised of one or more infrared lamps 226. Other heat sources may be used, such as a resistive heaters, hot plate, rapid thermal annealing (RTA), and the like. A preheat chamber (not shown) may be used to preheat the coated substrates to drive out the solvent, prior to heating to the full annealing temperature. When a preheat chamber is used, the substrates are typically heated to a temperature in the range of about 100 to about 30° C., for a time duration in the range of about 1 to 60 minutes. A vacuum-dry chamber may also be used to dry the solvents without applying heat. Note this annealing process can also happen under vacuum.

Heating or annealing to convert the CIG and Se precursor layers to the CIGS layer is carried out at any suitable temperature and duration to provide good grain growth. In some embodiments, heating is carried out in an inert environment at a temperature in the range of about 200 to about 65° C., and for a time duration in the range of about 1 to about 300 minutes.

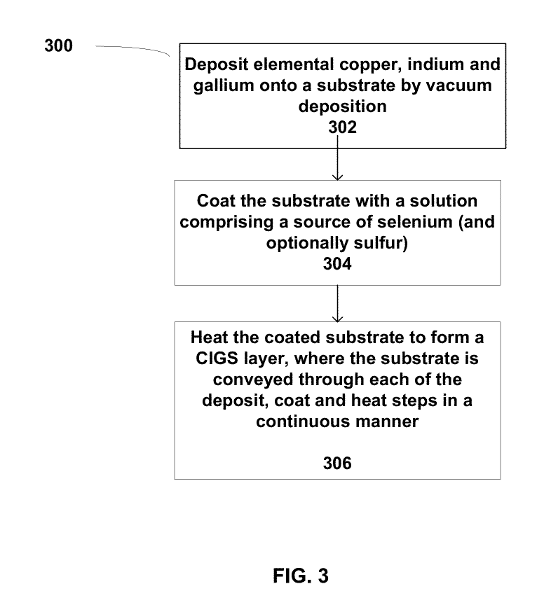

Methods of forming copper indium gallium diselenide (CIGS) layers for photovoltaic devices by inline processing are also disclosed. In some embodiments, a solution based selenization method in the formation of CIGS is provided. FIG. 3 is a flow chart illustrating a method 300 of forming CIGS layers for photovoltaic (PV) devices according to some embodiments of the present disclosure. Elemental copper (Cu), indium (In) and gallium (Ga) are deposited onto the substrate by vacuum deposition at step 302. The substrate is then coated with a solution comprising a source of selenium (and optionally a source of sulfur) dissolved in a solvent at step 304. The coated substrate is heated at step 306 to form the CIGS layer. The substrates are conveyed through each of the deposit, coat and heat steps in a continuous manner.

Elemental copper (Cu), indium (In) and gallium (Ga) are deposited onto the substrate by vacuum/non-vacuum deposition at step 302. Any suitable vacuum/non-vacuum deposition process may be used, such as but not limited to: evaporation, physical vapor deposition, electroplating, chemical vapor deposition, and the like. In some embodiments, these elemental metals are deposited by evaporation or sputtering from suitable metal targets, such as copper sputter targets, copper-gallium sputter targets and indium sputter targets.

A solution comprising a source of selenium dissolved in a solvent is coated onto the substrate at step 304. Any suitable solution may be used. In some embodiments, the solution is comprised of selenium dissolved in a suitable solvent(s). Examples of suitable solvents include without limitation: hydrazine, hydrous hydrazine, and/or a hydrazine-like solvent, such as ethanolamine, ethylene diamine (EDA), propylene diamine (PDA), dimethyl sulfoxide (DMSO, and mixtures thereof. The concentration of selenium in the solvent can be up to about 10 M, or more typically in the range of about 0.1 M to about 5 M. The viscosity of the solution may be controlled by adjusting the concentration of the Se in the solution. Generally, the viscosity of the solution is decreased by increasing the amount of solvent in the solution. In some embodiments, the solvent is a mixture of hydrazine with one or more co-solvents, such as water and/or EDA.

The selenium based solution is prepared by adding anhydrous hydrazine slowly to a vial containing elemental Se in an oxygen-free inert atmosphere.

Coating of the substrate with the selenium based solution at step 304 may be carried out by any suitable technique. In some embodiments the substrate is coated with the selenium based solution by dip coating. In some embodiments the substrate is coated with the selenium based solution by ink-jet type coating or printing. In some embodiments the substrate is coated with the selenium based solution by slit casting. In some embodiments the substrate is coated with the selenium based solution by gap coating. In further embodiments, the substrate is coated by spraying the selenium based solution on the substrate, or by wet chemical deposition onto the substrate. In a further aspect, roll-to-roll processing may be used on flexible substrates such as metal foils and polyimide films. In any of the above embodiments, an inline process and system may be used and configured to achieve high throughput.

Very high material utilization rates of selenium can be achieved according to embodiments of the present disclosure. Using the solution based selenization methods of the present disclosure, selenium is dissolved in the solvent and thus is completely available for coating onto the substrate. Prior art techniques based on vacuum evaporation have low material utilization rates since much of the selenium is evaporated onto the chamber walls and pumped out of the chamber by the vacuum pumps. Atmosphere evaporation of Se also exhibits low material utilization rate since once the source is heated up, the material will continue evaporating regardless whether the substrate is underneath the source or not. The heat inertia of the source doesn't allow an ON/OFF switching speed to save material when the substrate is being transferred in and out. In contrast, solution coating method according to some embodiments of the present disclosure can achieve desirable material utilization rates s by controlling the flow of the source liquid.

After coating of the substrate with the selenium based solution, the coated substrate is heated at step 306 to form the CIGS layer. A moderate, intermediate drying or heating step may first be performed to drive out the solvent. Heating or annealing to produce the CIGS layer is carried out at any suitable temperature and duration. In some embodiments, heating is carried out in an inert environment at a temperature in the range of about 200 to about 65° C., and for a duration in the range of about 1 to about 300 minutes.

In some embodiments, methods of the present disclosure enable facile control of the film thickness and/or the selenium concentration in the formed CIGS layer. In some embodiments, selenium concentration is varied by adjusting the concentration of selenium in the solution. In some embodiments, selenium concentration is varied by adjusting the supply rate of the solution as the substrate is coated. For example, when using an ink-jet type coating technique, the solution thickness can be tuned by adjusting the flow rate of the solution that is applied to the substrate. Alternatively, the substrate may be moved at a particular speed during the coating process, thereby varying the concentration of selenium coated onto the substrate.

The invention has been described in relation to particular examples, which are intended in all respects to be illustrative rather than restrictive. Various aspects and/or components of the described embodiments may be used singly or in any combination. It is intended that the specification and examples be considered as exemplary only, with a true scope and spirit of the invention being indicated by the claims.

What is claimed is:

1. An apparatus for production of copper indium gallium diselenide (CIGS) layers on a substrate, comprising:
at least one first chamber having one or more of copper, copper-gallium or indium targets and configured to sputter copper, copper-gallium and indium metals onto one or more substrates;
a second chamber configured to coat the one or more substrates with a solution comprising selenium;
a third chamber configured to heat the one or more substrates; and
an in-line system supporting the one or more substrates and configured to convey the one or more substrates sequentially through each of the first, second, and third chambers.

2. The apparatus of claim 1 wherein the second chamber further comprises a coater selected from any one of: an ink-jet coater, slit casting coater, gap coater, or spray coater.

3. The apparatus of claim 2 wherein the coater is comprised of an ink-jet coater.

4. The apparatus of claim 3 wherein the ink-jet coater further comprises a reservoir configured to house the solution and an outlet configured to deliver the solution to the substrate.

5. The apparatus of claim 4 wherein the outlet is elongated in a direction perpendicular to the direction of travel of the substrate.

6. The apparatus of claim 1 wherein the second chamber further comprises a coater and one or more sensors, the sensors configured to determine when a substrate passes beneath the coater.

7. The apparatus of claim 1 further comprising a chamber disposed between the at least one first chamber and the second chamber, the chamber operable as a loadlock.

8. The apparatus of claim 1 wherein the third chamber further comprises one or more infrared lamps.

9. A method for the formation of copper indium gallium diselenide (CIGS) layers on a substrate, comprising:
depositing copper, indium and gallium metal onto one or more substrates using a vacuum-based technique;
coating the one or more substrates with a solution comprising selenium; and
heating the coated substrate, wherein the one or more substrates are conveyed though each of the depositing, coating, and heating steps in an in-line manner.

10. The method of claim 9 wherein the step of coating is performed by any one of: dip coating, ink-jet type coating, slit casting, or gap coating.

11. The method of claim 9 wherein the step of coating is performed by ink-jet coating or ink-jet printing.

12. The method of claim 9 wherein the solution is comprised of selenium dissolved in a solvent.

13. The method of claim 12 wherein the solvent is comprised of any one of: hydrazine, hydrous hydrazine, ethanolamine, ethylenediamine (EDA), propylenediamine (PDA), dimethyl sulfoxide (DMSO) or mixtures thereof.

14. The method of claim 12 wherein the concentration of selenium in the solvent is up to about 10 M.

15. The method of claim 12 wherein the concentration of selenium in the solvent is in the range of about 0.1 M to about 5 M.

16. The method of claim 9 wherein the heating step is carried out in an inert environment at a temperature in the range of about 200 to about 65° C., and for a duration in the range of about 1 to about 300 minutes.

17. The method of claim 9 further comprising, preheating the substrate prior to the heating step.

18. The method of claim 9 wherein the CIGS layer is formed having a desired thickness by varying during the coating step, any one: thickness of the solution, concentration of Se in the solution, viscosity of the solution, or speed of coating the solution on the substrate.

19. The method of claim 9 wherein the step of depositing is comprised of any one of:
evaporation, physical vapor deposition, chemical vapor deposition, or electroplating.
